(19) United States
(12) Patent Application Publication
(10) Pub. No.: US 2026/0012205 A1
(43) Pub. Date: Jan. 8, 2026

(54) SYSTEM AND METHOD FOR POLAR DECODING

(71) Applicant: JIO PLATFORMS LIMITED, Ahmedabad, Gujarat (IN)

(72) Inventors: Dileep Reddy VANAVASAM, Hyderabad, Telangana (IN); Sagar BISSA, Jodhpur, Rajasthan (IN); Smriti SINHA, Chandausi, Uttar Pradesh (IN); Selva Ganapathy P, Sivakasi, Tamil Nadu (IN); Jaganathan G, Namakkal, Tamil Nadu (IN); Aayush BHATNAGAR, Navi Mumbai, Maharashtra (IN); Pradeep Kumar BHATNAGAR, Navi Mumbai, Maharashtra (IN)

(73) Assignee: JIO PLATFORMS LIMITED, Ahmedabad, Gujarat (IN)

(21) Appl. No.: 18/879,990

(22) PCT Filed: Aug. 30, 2023
(86) PCT No.: PCT/IB2023/058567

§ 371 Date: Dec. 30, 2024

(30) Foreign Application Priority Data
Aug. 31, 2022 (IN) 202221049806

(51) Int. Cl. H03M 13/13; H03M 13/09; H04L 1/00

(52) U.S. Cl. CPC H03M 13/13; H03M 13/09; H04L 1/0045; H04L 1/0057

(57) ABSTRACT

The present disclosure provides a system and method for polar decoding in a communication system. A polar decoder includes a core block including a successive cancellation decoder and a list decoder, and a cyclic redundancy check (CRC) module, wherein the core block stores one or more pre-calculated reliability sequence for decoding the received encoded data bits.

### RESERVATION OF RIGHTS

A portion of the disclosure of this patent document contains material, which is subject to intellectual property rights such as, but are not limited to, copyright, design, trademark, Integrated Circuit (IC) layout design, and/or trade dress protection, belonging to Jio Platforms Limited (JPL) or its affiliates (hereinafter referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

### FIELD OF DISCLOSURE

The embodiments of the present disclosure generally relate to decoder implementation for communication networks. More particularly, the present disclosure relates to a field programmable gate array (FPGA) implementation of a polar decoder for physical uplink control channel (PUCCH) format 2 fifth generation (5G) new radio (NR) physical layer.

### BACKGROUND OF DISCLOSURE

The following description of related art is intended to provide background information pertaining to the field of the disclosure. This section may include certain aspects of the art that may be related to various features of the present disclosure. However, it should be appreciated that this section be used only to enhance the understanding of the reader with respect to the present disclosure, and not as admissions of prior art.

Polar codes have been adopted as the coding scheme in the control channel of the 3rd Generation Partnership Project (3GPP) New Radio (NR) standard for 5G. Typically, when a polar decoder is implemented on a Radio Frequency System-on-Chip (RFSoC), various limitations like inefficient utilization of resources, higher utilization of look-up tables (LUTs) and flip-flops are observed.

There is, therefore, a need in the art to provide a system and a method that can overcome the shortcomings of the existing prior arts.

### OBJECTS OF THE PRESENT DISCLOSURE

Some of the objects of the present disclosure, which at least one embodiment herein satisfies are as listed herein below.

An object of the present disclosure is to provide an efficient decoder system.

An object of the present disclosure is to provide a Field Programmable Gate Array (FPGA) implementation of a polar decoder for physical uplink control channel (PUCCH) format 2 5G new radio (NR) physical layer.

An object of the present disclosure is to reduce resource consumption on programmable logic (PL) side.

An object of the present disclosure is to reduce higher consumption of look-up tables (LUTs).

An object of the present disclosure is to improve the generation mechanism of the reliability sequence in decoder.

### SUMMARY

This section is provided to introduce certain objects and aspects of the present disclosure in a simplified form that are further described below in the detailed description. This summary is not intended to identify the key features or the scope of the claimed subject matter.

In one aspect, the present disclosure relates to a polar decoder. The polar decoder includes a core block including a successive cancellation (SC) decoder and a list decoder, and a cyclic redundancy check (CRC) module, wherein the core block is configured to store one or more pre-calculated reliability sequence for decoding received encoded data bits.

In some embodiments, the core block may be configured to select the one or more pre-calculated reliability sequence based on an input combination of encoded bits ‘E’ and actual payload bits ‘K’ for the decoding.

In some embodiments, the core block may be configured to perform sorting on the received encoded bits to decode one or more code words, wherein the number of steps for sorting to obtain the one or more code words may be based on a list size associated with the polar decoder.

In some embodiments, the core block may be configured to provide an output of one or more code words to the CRC module based on the decoding.

In some embodiments, the CRC module may be configured to determine whether the one or more code words pass or fail a CRC test based on a bit position and generate an output of the one or more code words based on a CRC pass and a lowest path metric.

In some embodiments, the CRC module may be configured to output a first code word of the one or more code words based on a CRC fail obtained for all of the one or more code words.

In another aspect, the present disclosure relates to a method for decoding in a polar decoder. The method includes storing, by a core block, one or more pre-calculated reliability sequences, decoding, by the core block, the received encoded data bits based on the one or more pre-calculated reliability sequences to output one or more code words to a cyclic redundancy check (CRC) module, and performing, by a cyclic redundancy check (CRC) module, a CRC on the one or more code words.

In some embodiments, the method may include selecting, by the core block, at least one pre-calculated reliability sequence from the one or more pre-calculated reliability sequences based on an input combination of encoded bits ‘E’ and actual payload bits ‘K’ for the decoding.

In some embodiments, the method may include performing, by the core block, sorting on the received encoded bits to decode one or more code words, wherein the number of steps for sorting to obtain the one or more code words may be based on a list size associated with the polar decoder.

In some embodiments, the method may include determining, by the CRC module, whether the one or more code words pass or fail a CRC test based on a bit position and generating, by the CRC module, an output of the one or more code words based on a CRC pass and a lowest path metric.

In some embodiments, the method may include generating, by the CRC module, an output of a first code word of the one or more code words based on a CRC fail for all the one or more code word.

In one another aspect, the present disclosure relates to a receiver in a base station (BS). The receiver includes a core block including a successive cancellation (SC) decoder and a list decoder, and a cyclic redundancy check (CRC) module, wherein the core block stores one or more pre-calculated reliability sequence for decoding received encoded data bits.

In yet another aspect, the present disclosure relates to a non-transitory computer readable medium that includes one or more instructions stored thereupon that when executed by a processor causes the processor to perform operations including receiving encoded data bits from a transmitter, storing one or more pre-calculated reliability sequences, decoding the received encoded data bits based on the one or more pre-calculated reliability sequences to output one or more code words to a cyclic redundancy check (CRC) module, and performing a CRC on the one or more code words.

### BRIEF DESCRIPTION OF DRAWINGS

The accompanying drawings, which are incorporated herein, and constitute a part of this disclosure, illustrate exemplary embodiments of the disclosed methods and systems in which like reference numerals refer to the same parts throughout the different drawings. Components in the drawings are not necessarily to scale, emphasis instead being placed upon clearly illustrating the principles of the present disclosure. Some drawings may indicate the components using block diagrams and may not represent the internal circuitry of each component. It will be appreciated by those skilled in the art that disclosure of such drawings includes the disclosure of electrical components, electronic components or circuitry commonly used to implement such components.

FIG. 1 illustrates an exemplary network architecture (100) in which or with which a proposed polar decoder may be implemented, in accordance with embodiments of the present disclosure.

FIG. 2 illustrates an exemplary high-level block diagram (200) of a polar decoder, in accordance with an embodiment of the present disclosure.

FIG. 3 illustrates an exemplary pin diagram representation (300) of the polar decoder, in accordance with an embodiment of the present disclosure.

FIG. 4 illustrates a flow chart of an example method (400) for successive cancellation decoding with resource reduction, in accordance with embodiments of the present disclosure.

FIG. 5 illustrates a flow chart of an example method (500) of list decoding with sorting algorithm, in accordance with embodiments of the present disclosure.

FIG. 6 illustrates an exemplary computer system (600) in which or with which embodiments of the present disclosure may be implemented.

The foregoing shall be more apparent from the following more detailed description of the disclosure.

### DETAILED DESCRIPTION OF DISCLOSURE

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Also, it is noted that individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive—in a manner similar to the term “comprising” as an open transition word-without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

In some aspects, the present disclosure provides storing a pre-calculated reliability sequence information and selecting a required sequence information from the stored pre-calculated reliability sequence information. In some embodiments, selecting the required sequence may be based on inputs passed from a programming system (PS) to a programming logic (PL) in a field programmable gate array (FPGA) associated with a polar decoder.

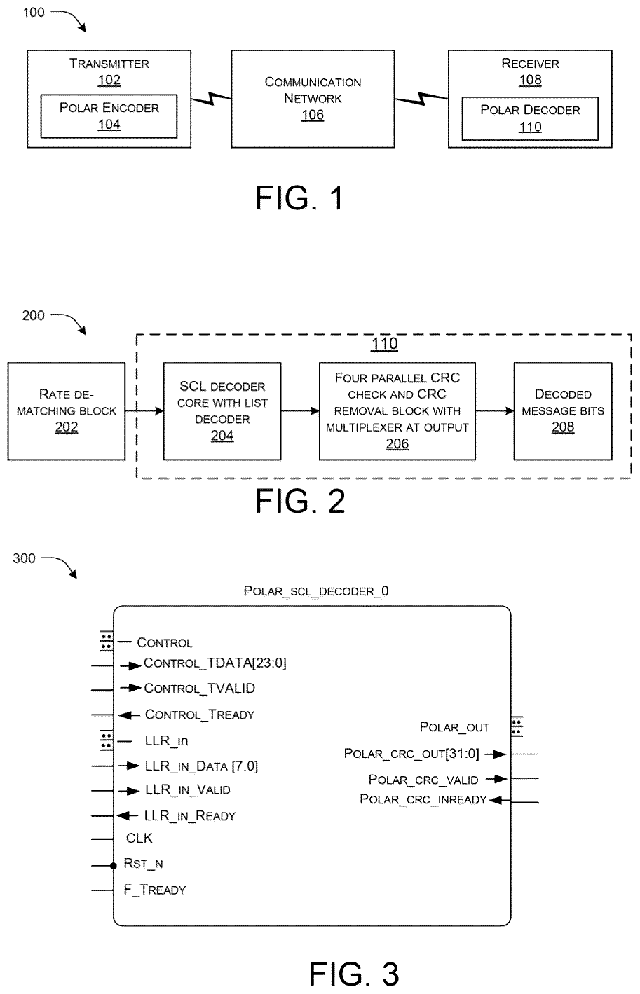

The various embodiments throughout the disclosure will be explained in more detail with reference to FIGS. 1-6.

FIG. 1 illustrates an exemplary network architecture (100) in which or with which a proposed polar decoder may be implemented, in accordance with embodiments of the present disclosure.

Referring to FIG. 1, the network architecture (100) includes a transmitter (102) including a polar encoder (104). In some embodiments, the transmitter (102) transmits an encoded information through a communication network (106) to a receiver (108). The receiver (108) may include a polar decoder (110) for decoding the encoded information received from the transmitter (102). In some embodiments, the communication network (106) may include a fifth generation (5G) communication network. Further, the transmitter (102) and the receiver (108) may include the polar encoder (104) and the polar decoder (110), respectively, operating in physical uplink control channel (PUCCH) format 2.

In one embodiment, the transmitter (102) may include a base station or an access point and the receiver (108) may include a user equipment (UE). In another embodiment, the transmitter (102) may include the UE and the receiver (108) may include the base station or the access point. In one embodiments, the base station or the access point may serve an outdoor small cell (ODSC).

In some embodiments, the polar decoder (110) may include storing pre-calculated reliability sequence information used for decoding the information encoded by the polar encoder (104).

Although FIG. 1 shows exemplary components of the network architecture (100), in other embodiments, the network architecture (100) may include fewer components, different components, differently arranged components, or additional functional components than depicted in FIG. 1. Additionally, or alternatively, one or more components of the network architecture (100) may perform functions described as being performed by one or more other components of the network architecture (100).

FIG. 2 illustrates an exemplary high-level block diagram (200) of a polar decoder, in accordance with an embodiment of the present disclosure.

Referring to FIG. 2, the block diagram (200) includes a rate de-matching block (202), and a decoder block (110) comprising a core block (204) including a successive cancellation (SC) decoder with list decoder, a cyclic redundancy check (CRC) module or a CRC check and removal block (206), and an output block (208) including the decoded bits. In some embodiments, the rate de-matching block (202) may perform rate de-matching operation on the encoded information bits received from the polar encoder (104). In some embodiments, the core block (204) may perform decoding based on reliability sequence and parity check bits with a list size of four. Further, the polar decoder (200) may implement the CRC module (206) for performing CRC6 on the received encoded bits to determine integrity of the payload received. Further, the polar decoder (200) makes use of min-sum function for performing its decoding operation traversing the complete binary tree for a particular N, where N is the number of decoded bits which is formed at the output block (208). Subsequently, the transmitted message bits may be picked from most reliable positions defined by a reliability sequence. In some embodiments, the reliability sequence is pre-calculated and stored in a programming logic (PL) of the polar decoder (200). At the final stage, the CRC module (206) does the CRC check of the decoded message bits (K) and produces the CRC pass or fail result along with actual payload (A) formed after removing the CRC bits. This operation of path metric calculation and sorting is being done during traversal of successive cancellation decoding operation and four such ‘u’ values are calculated which are finally provided to four parallel CRC decoders, and a multiplexer (not shown) selects the output to be given from the four CRC decoders based on the CRC flag result.

In some embodiments, sorting may be performed on the received encoded bits to decode one or more code words, wherein the number of steps for sorting to obtain the one or more code words is based on a list size associated with the polar decoder. In some embodiments, the list size may include a number of parallel code words to be maintained in the decoder by which the probability of decoding increases. In an example embodiment, the list size may be four.

By way of example, without limitations, the polar decoder (200), based on PUCCH format 2, may support 56 combinations of ‘E’ (i.e., rate de-matched encoded bits) and ‘A’ (i.e., actual message bits without CRC) and manages to achieve a sensitivity level of-108 dBm with use of a list size of four. In addition, pre-calculated reliability sequence information is stored and required sequence is picked on basis of inputs passed from the PS to the PL facilitating a reduced resource consumption on the PL side

For example, a set of supported combinations of ‘E’ and ‘A’ is shown below in Table 1. In some embodiments, for each combination pair, there is a bitmap stored inside the decoder (200) which is picked using a multiplexer. Some combinations have the exact same bitmap so as to save on the resources. As may be appreciated, combinations having the same bitmap are picked for those combinations instead of storing the same bitmap at different addresses.

TABLE 1

| | A (actual payload bits after CRC |
|---|---|
| E (rate de-matched encoded bits) | bits removal) |
| 32 | 12-19 |
| 48 | 12-19 |
| 64 | 12-19 |
| 80 | 12-19 |
| 96 | 12-19 |
| 112 | 12-19 |
| 128 | 12-19 |

Referring to FIG. 2, the core block (204) performs the decoding operation. In some embodiments, the SC and list decoder in the core block may (204) receive N (encoded bits), E (rate de-matched encoded bits), and K (payload with CRC bits) as control information and starts its decoding operation.

In some embodiments, E, the rate de-matched encoded bits that may be transmitted using the available resources is calculated as follows:

$$E = Prb * Symb * 8 * 2$$

Where Prb is the number of resource blocks, and Symb is the number of symbols based on modulation order used.

In some embodiments, the total number of encoded uplink control information (UCI) bits is defined as:

$$k = no . of bits for ( scheduling request ( SR ) + hybrid automatic repeat request ( HARQ ) + channel state information ( CSI ) )$$

and the no. of payload bits after removing CRC bits is given as A=k−6.

In an embodiment, the SCL decoder core (204) may implement min-sum function to perform the successive cancellation decoding operation. The min-sum function includes the following steps:
(i) Left node operation: Based on L[ui] (belief calculated for the i^{th} bit), where L is the calculated min-sum for the ith bit (0<i<N−1). If ith bit position is frozen bit, then the hard decision is ui=0 otherwise, if L(ui)>=0, ui=0, else ui=1.
For example, L(ui)=f(r1,r2)=sign(r1)·sign(r2)·min(|r1|,|r2|), where r1 and r2 are beliefs received from parent node (ii) Right node operation: for the right node, belief is calculated in the following manner—
If ui=0 (from left node) then g (L1, L2)=r2+r1
If ui=1 (from left node) then g (L1, L2)=r2−r1
where g (L1,L2)=g (r1,r2) is the calculated belief for the next successive bit position ((i+1)th bit) where r2 and r1 are the 2 beliefs received at the parent node.
After g is calculated, u(i+1) is calculated using the above mentioned left node operation.

In some embodiments, the right node u is decoded using similar condition as used in left node.

In an embodiment, the list decoder inside the core block (204) works

on four parallel decoders and provides four decoded code words among which one is selected as output based on a CRC flag.

Referring to FIG. 2, the CRC module (206) may receive one or more decoded bits from the core block (204). In an embodiment, the core block (204) may select the k bits out of N decoded bits and pass it to the CRC module (206). The CRC module (206) may check for data integrity based on one or more bit values in the decoded bits. In an example embodiment, the bit value at the 24th bit position in a 32-bit output indicates whether CRC check was passed (bit 1) or failed (bit 0) and the remaining least significant byte (LSB) bits indicate the payload or message bits (208) after the removal of the CRC bits.

Based on the above discussion, using the pre-calculated reliability sequence and a pre-stored bit map aids in reducing the resource utilization. Table 2 below indicates a detailed analysis of total resource utilization.

TABLE 2

| | | | Block | | |
|---|---|---|---|---|---|
| Module | LUTs | FF | RAM | URAM | DSPs |
| SCL decoder core | 13300 | 2464 | 12 | 0 | 0 |
| CRC module | 295 | 308 | 0 | 0 | 0 |
| Total resources for | 13581 | 2804 | 12 | 0 | 0 |
| Polar decoder | | | | | |
| Resources Utilization | 3.19 | 0.33 | 1.11 | 0 0 | |
| in % | | | | | |
| Total Resources | 425280 | 850560 | 1080 | 80 | 4272 |
| Available | | | | | |

As may be seen in the above table, the polar decoder (200) may seem to use only 3% of the total look up tables (LUTs) present on a radio frequency system on chip (RFSoC), a 0.33% of flip-flops i.e., minimal amount of flip flops, and 1% block random access memory (BRAM) to provide a sensitivity of −108 dBm. Therefore, the resource utilization factor is very less compared to other mechanisms.

A person of ordinary skill in the art will appreciate that the exemplary block diagram (200) may be modular and flexible to accommodate any kind of changes in the decoder (110).

FIG. 3 illustrates an exemplary pin diagram representation (300) of the polar decoder, in accordance with an embodiment of the present disclosure.

Referring to FIG. 3, the SCL polar decoder (300) includes three advanced extensible interface (AXI4-stream) interfaces namely Control, s_axis, and Polar_out. The details of the pins may be explained as follows:

1. Control: The control includes 24-bit data structure which may be divided into three 8 bits control information inside. For example, without limitations bits [23:16] is for ‘E’, bits [15:8] is for ‘N’, and bits [7:0] is for ‘k’. In an embodiment, the SCL polar decoder (300) accept one control data and sets a Control_TREADY pin low, so that, the SCL polar decoder (300) may start to accept next control information once the previous code block is decoded.

2. LLR_in: This includes data ports for accepting Log-Likelihood Ratio (LLR) from rate recovery module (1 LLR at a time). It may only accept LLRs after at least one control data is accepted.

3. Polar_out: This includes output interface with the following format->bits [31:24] are reserved, bit [23:23] is CRC flag, and bits [22:0] specify the actual payload.

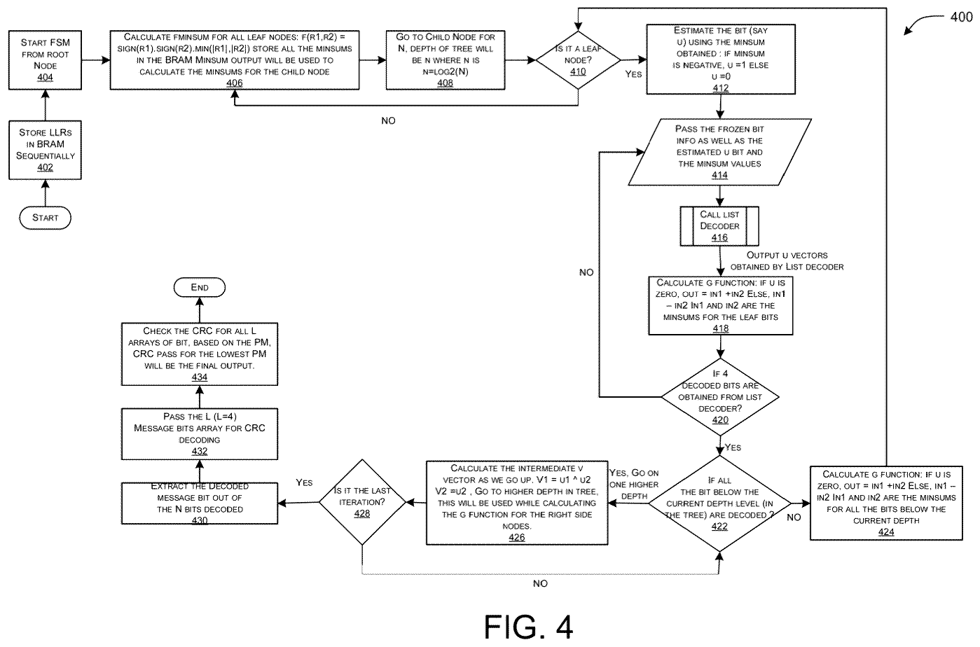

FIG. 4 illustrates a flow chart of an example method (400) for successive cancellation decoding with resource reduction, in accordance with embodiments of the present disclosure.

Referring to FIG. 4, the method (400) may include at step 402, storing all the LLRs from rate de-matching block inside identical BRAMs in a sequential manner.

Referring to FIG. 4, upon storing the LLRs, the method (400) may further include at step 404, starting a finite state machine (FSM) from a root node. The method (400) may further include at step 406, calculating a Fminsum for All Leaf Nodes as f(r1,r2)=sign(r1)·sign(r2)·min(|r1|,|r2|) and storing all the minsums in the BRAM, wherein the Minsum output will be used to calculate the minsums for the child node.

The method (400) may further include at step 408, proceeding to a child node for N. In some embodiments, the depth of tree will be ‘n’, where n is defined as n=log2(N). The method (400) may include at step 410, determining if the child node is a leaf node. If the child node is a leaf node, the method (400) may include at step 412, estimating the bit ‘u’ using the minsum obtained. For example, if minsum is negative, u=1 else u=0. On the other hand, if the child node is not a leaf node, the method (400) includes processing step 406. The method (400) may include at step 414, passing the frozen bit info as well as the estimated ‘u’ bit and the minsum values to the list decoder. The method (400) may include at step 416, calling the list decoder. In some embodiments, the list decoder outputs a set of vectors ‘u’.

Referring to FIG. 4, the method (400) may include at step 418, calculating a belief value as ‘g’ function. For example, if vector ‘u’=0, out=in1+in2 and if ‘u’=1, the out=in1−in2, where in1 and in2 are the minsums for the leaf bits. The method (400) may include at step 420, determining if four decoded bits are obtained from the list decoder. If four decoded bits are obtained, the method (400) may include at step 422, determining if all the bit below the current depth level are decoded. If all the bits below the current depth level are decoded, the method (400) may include at step 426, calculating an intermediate vector V as V1=u1\hat{ }u2 and V2=u2. In some embodiments, V1 and V2 may be used to calculate G function for the right nodes when reaching higher depth in tree. On the other hand, if all the bits below the current depth level are not decoded, the method (400) may include at step 424, calculating the ‘g’ function such that, if u is zero, out=in1+in2 else, in1−in2, where in1 and in2 are the minsums for all the bits below the current depth. Referring to step 420, on the other hand, if four decoded bits are not obtained from list decoder, the method (400) may include processing the step 414.

Referring to FIG. 4, the method (400) may include at step 428, determining if the current iteration is the last iteration. If the current iteration is the last iteration, the method (400) may include at step 430, extracting the decoded message bit out of the N bits decoded. The method (400) may include at step 432, passing the L (L=4) message bits array for CRC decoding. The method (400) may further include at step 434, checking the CRC for all L arrays of bit, based on the path metric (PM), wherein the CRC pass for the lowest PM may be considered the final output. On the other hand, if the current iteration is not the last iteration, the method (400) may include processing the step 422.

In summary, the method (400) may include the following stages: Firstly, all the LLRs from rate de-matching block are stored inside two identical BRAMs (basically same data is stored in both BRAMs) and input ready signal is de-asserted to indicate to rate de-matching block that internal processing is started. Secondly, once the all LLRs are stored, SCL decoding FSM starts from root node. The min-sums are calculated for the child nodes (reading N/2 LLRs from BRAM1and rest N/2 LLRs from BRAM2). All the min-sums are stored in BRAM1 at each depth of the binary tree and L/2 min-sums are passed to child node. The FSM will keep going till it has reached left most leaf node. Thirdly, if it is not a leaf node then min-sum calculations are continued till leaf node is reached. Fourthly, once the leaf node is reached, ‘u’ is calculated and list decoder is called to update the path metric. Next, after decoding the bit on left, right operation happens where belief is calculated on the basis of result from left node operation. Based on the belief, ‘u’ is estimated, and list decoder is called. Further, after each list decoder call, sorted list of four estimated u is received that are used for traversing the binary tree. Thereafter, the tree may be traversed, once the bits are decoded at a particular child node, Upper (U) operation happens and then on reaching a higher depth a check is done if all the bits below the child nodes are decoded. If that is not the case then right side of tree is traversed, and right operation is performed. Further, a left operation is continued, till the leaf node is reached and decoding continues in the same manner. Finally, at the output, four codewords are available sorted in increasing order of the Path Metric. All codewords are passed through CRC check and whichever gives CRC pass result with the least Path Metric, which is selected by a mux to be given at the output. If all the CRC are failing, then the first codeword is selected at the output with a CRC FAIL result.

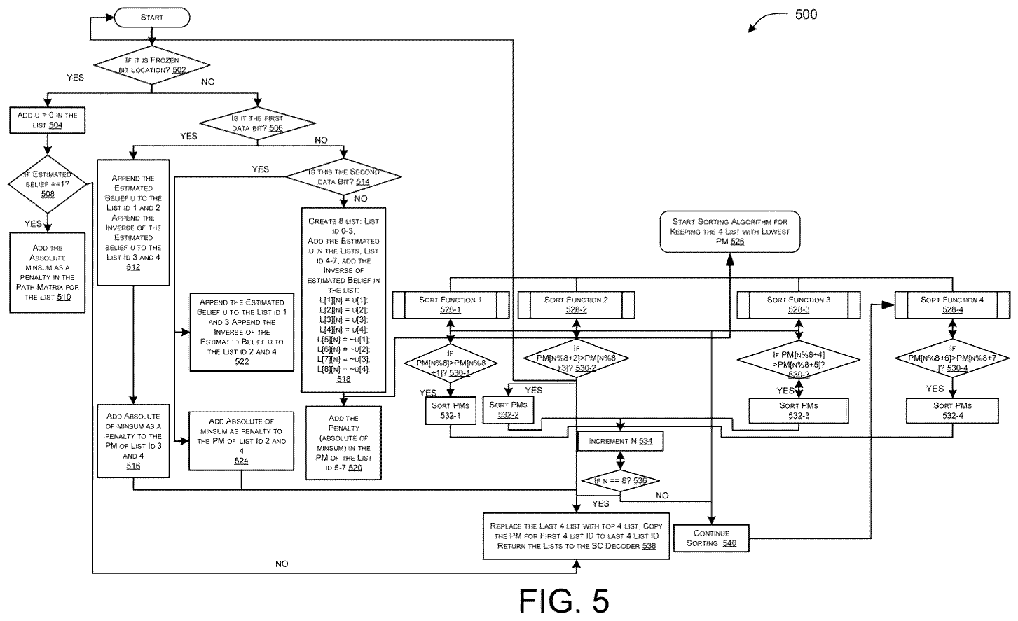

FIG. 5 illustrates a flow chart of an example method (500) of list decoding with sorting algorithm, in accordance with embodiments of the present disclosure.

In some embodiments, sorting of the list may be performed based on a list size, wherein the list size may be defined by number of parallel code words to be maintained in the decoder by which the probability of decoding increases. In an example embodiment, a list size of 4 may be implemented. However, for example, when the list size grows to eight at a node, a further traversal may be done using at least four decoders. The four decoders may assist in selecting at least four best code words out of eight code words based on the PM. Further, by sorting the array of 8 path metrics in the ascending order and pick the first 4 code words the tree traversal is continued. The sorting is done in 8 clock cycles and using 4 comparators, each comparator takes two inputs numbers and provides two sorted outputs minimum and maximum of two numbers. The proposed method employs less resources as well as minimum clock cycles to complete the sorting operation thereby contributing in achieving a low latency with high performance. The sorting algorithm is depicted in the below exemplary Table 3.

TABLE 3

| Sequence to be | | | | | | | | |
|---|---|---|---|---|---|---|---|---|
| sorted | A | B | C | D | E | F | G | H |
| Step 1 | A1 = | B1 = | C1 = | D1 = | E1 = | F1 = | G1 = | H1 = |
| | Min(A, B) | Max(A, B) | Min(C, D) | Max(C, D) | Min(E, F) | Max(E, F) | Min(G, H) | Max(G, H) |
| Step 2 | A2 = | B2 = | C2 = | D2 = | E2 = | F2 = | G2 = | H2 = |
| | Min(A1, H1) | Min(B1, C1) | Max(B1, C1) | Min(D1, E1) | Max(D1, E1) | Min(F1, G1) | Max(F1, G1) | Max(A1, H1) |
| Step 3 | A3 = | B3 = | C3 = | D3 = | E3 = | F3 = | G3 = | H3 = |
| | Min(A2, B2) | Max(A2, B2) | Min(C2, D2) | Max(C2, D2) | Min(E2, F2) | Max(E2, F2) | Min(G2, H2) | Max(G2, H2) |
| Step 4 | A4 = | B4 = | C4 = | D4 = | E4 = | F4 = | G4 = | H4 = |
| | Min(A3, H3) | Min(B3, C3) | Max(B3, C3) | Min(D3, E3) | Max(D3, E3) | Min(F3, G3) | Max(F3, G3) | Max(A3, H3) |
| Step 5 | A5 = | B5 = | C5 = | D5 = | E5 = | F5 = | G5 = | H5 = |
| | Min(A4, B4) | Max(A4, B4) | Min(C4, D4) | Max(C4, D4) | Min(E4, F4) | Max(E4, F4) | Min(G4, H4) | Max(G4, H4) |
| Step 6 | A6 = | B6 = | C6 = | D6= | E6 = | F6 = | G6 = | H6 = |
| | Min(A5, H5) | Min(B5, C5) | Max(B5, C5) | Min(D5, E5) | Max(D5, E5) | Min(F5, G5) | Max(F5, G5) | Max(A5, H5) |
| Step 7 | A7 = | B7 = | C7 = | D7 = | E7 = | F7 = | G7 = | H7 = |
| | Min(A6, B6) | Max(A6, B6) | Min(C6, D6) | Max(C6, D6) | Min(E6, F6) | Max(E6, F6) | Min(G6, H6) | Max(G6, H6) |
| Step 8 (Sorted | A8 = | B8 = | C8 = | D8 = | E8 = | F8 = | G8 = | H8 = |
| sequence) | Min(A7, H7) | Min(B7, C7) | Max(B7, C7) | Min(D7, E7) | Max(D7, E7) | Min(F7, G7) | Max(F7, G7) | Max(A7, H7) |

As mentioned, the sorting method works as follows: the input A, B, C, D, E, F, G and H may be obtained and in the table, every intermediate steps are named as A1, A2, A3, A4, A5, A6, A7, and A8, respectively, to complete the sorting

Step 1 may include comparing the run of A and B, C and D, E and F, G and H. These are compared and placed at Al to H1 location. In an example, A1=min(A,B), B1=max(A,B), C1=min(C,D), D1=max(C,D), E1=min(E,F), F1=max(E,F), G1=min(G,H), H1=max(G,H).

Step 2 may include executing a comparison of Al to H1 and storing the result of the comparison as A2 to H2. In an example, A2=Min(A1,H1), B2=Min(B1,C1), C2=Max(B1,C1), D2=Min(D1,E1), E2=Max(D1,E1), F2=Min(F1,G1), G2=Max(F1,G1), H2=Max(A1,H1).

Step 3 may include repeating the same operations as mentioned in the step 1 on A2 to H2 and storing the output as A3 to H3 which may be used in step 4.

Step 4 may include repeating the same operations as mentioned in the step 2 on A3 to H3 and storing the output as A4 to H4 which may be used in step5.

Step 5 may include repeating the same operations as mentioned in the step 1 on A4 to H4 and storing the output as A5 to H5 that may be used by step 6.

Step 6 may include repeating the same operations as mentioned in the step 2 on A5 to H5 and storing the output as A6 to H6 which may be used by step7.

Step 7 may include repeating the same operations as mentioned in the step 1 on A6 to H6 and storing the output as A7 to H7 which may be used by step 8.

Step 8 may include repeating the same operations as mentioned in the step 2 on A7 to H7 and storing the output as A8 to H8, wherein the output A8 to H8 provides the sorted data.

Referring to FIG. 5, the method (500) may include at step 502, determining if a particular bit at given location in a list of decoded bits is a frozen bit. If it is a frozen bit, the method (500) may include at step 504, adding ‘u’=0 in the list. The method (500) may further include at step 508, determining if the estimated belief is equal to one. If the estimated belief is equal to one, the method (500) may include at step 510 adding the absolute minsum as a penalty in the PM for the list. On the other hand, if the estimated belief is not equal to one, the method (500) may include at step 538 replacing the last four list with top four list, copying the PM for the first 4 list IDs to last 4 List IDs, and returning the lists to the SC decoder. On the other hand, if the particular bit at the given location is not a frozen bit, the method (500) may include at step 506, determining if the particular bit at the given location is a first data bit. If the particular bit at the given location is a first data bit, the method (500) may include at step 512, appending the estimated belief ‘u’ to the list Id 1 and 2 and appending the inverse of the estimated belief u to the list Id 3 and 4. The method (500) may further include at step 516, adding an absolute of minsum as a penalty to the PM of List Id 3 and 4 and processing the step 538.

On the other hand, if the particular bit at the given location is not a first data bit, the method (500) may include at step 514, determining if the particular bit at the given location is a second data bit. If the particular bit is the second data bit, the method (500) may include at step 522, appending the estimated belief u to the List id 1 and 3 and appending the Inverse of the estimated belief u to the List id 2 and 4. The method (500) may further include at step 524, adding absolute of minsum as penalty to the PM of List Id 2 and 4 and processing the step 538. On the other hand, if the particular bit is not the second data bit, the method (500) may include at step 518 creating a list of eight decoded bits and adding the estimated belief ‘u’ in the list for list id 0-3 and adding inverse of the estimated belief ‘u’in the list for the list Ids 4-7. For example, without limitations, L[1][n]=u[1], L[2][n]=u[2], L[3][n]=u[3], L[4][n]=u[4], L[5][n]=˜u[1], L[6][n]=˜u[2], L[7][n]=˜u[3], L[8][n]=˜u[4]. The method (500) may include at step 526, performing a sorting algorithm for keeping one or more list IDs with lowest PM. In some embodiments, at least 4 IDs with lowest PM may be sorted. The method (500) may further include at step 522, adding an absolute of minsum as a penalty to the PM of List IDs 5-7.

Referring to FIG. 5, the method (500) may include at step 528-1, performing sort function 1 on the list of decoded bits with lowest PM. The method (500) may further include at step 530-1, determining if PM[n % 8]>PM[n % 8+1]. If the result of the determination is positive, the method (500) may include at step 532-1, sorting PMs. Further, the method (500) may include at step 534, incrementing ‘N’. The method may further include at step 536, determining if the number of elements in the list has reached eight i.e., if N=8. If N=8, the method (500) may include processing the step 538. On the other hand, if N is not equal to 8, the method (500) may include at step 540, continuing the sort function. On the other hand, if PM[n % 8] is not greater than PM[n % 8+1], the method (500) may include processing the step 528-1.

Referring to FIG. 5, the method (500) may include at step 528-2, performing sort function 2 on the list of decoded bits with lowest PM. The method (500) may further include at step 530-2, determining if PM[n % 8+2]>PM[n % 8+3]. If the result of the determination is positive, the method (500) may include at step 532-2, sorting PMs. Further, the method (500) may include at step 534, incrementing ‘N’. The method may further include at step 536, determining if the number of elements in the list has reached eight i.e., if N=8. If N-8, the method (500) may include processing the step 538. On the other hand, if N is not equal to 8, the method (500) may include at step 540, continuing the sort function. On the other hand, if PM[n % 8+2] is not greater than PM[n % 8+3], the method (500) may include processing the step 528-2.

Referring to FIG. 5, the method (500) may include at step 528-3, performing sort function 3 on the list of decoded bits with lowest PM. The method (500) may further include at step 530-3, determining if PM[n % 8+4]>PM[n % 8+5]. If the result of the determination is positive, the method (500) may include at step 532-3, sorting PMs. Further, the method (500) may include at step 534, incrementing ‘N’. The method may further include at step 536, determining if the number of elements in the list has reached eight i.e., if N=8. If N=8, the method (500) may include processing the step 538. On the other hand, if N is not equal to 8, the method (500) may include at step 540, continuing the sort function. On the other hand, if PM[n % 8+4] is not greater than PM[n % 8+5], the method (500) may include processing the step 528-3.

Referring to FIG. 5, the method (500) may include at step 528-4, performing sort function 4 on the list of decoded bits with lowest PM. The method (500) may further include at step 530-4, determining if PM[n % 8+6]>PM [n % 8+7]. If the result of the determination is positive, the method (500) may include at step 532-4, sorting PMs. Further, the method (500) may include at step 534, incrementing ‘N’. The method may further include at step 536, determining if the number of elements in the list has reached eight i.e., if N=8. If N=8, the method (500) may include processing the step 538. On the other hand, if N is not equal to 8, the method (500) may include at step 540, continuing the sort function. On the other hand, if PM[n % 8+6] is not greater than PM[n % 8+7], the method (500) may include processing the step 528-4.

A person of ordinary skill in the art will appreciate that these are mere examples, and in no way, limit the scope of the present disclosure.

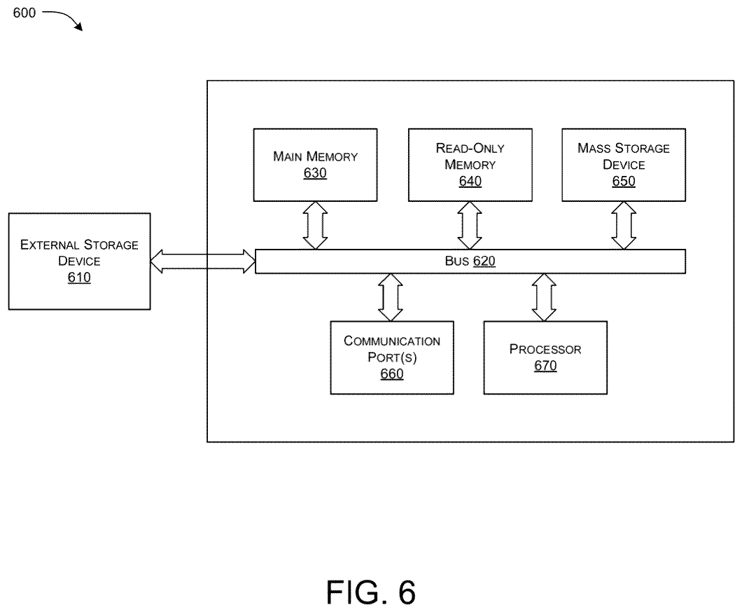

FIG. 6 illustrates an exemplary computer system (600) in which or with which embodiments of the present disclosure may be utilized.

As shown in FIG. 6, the computer system (600) may include an external storage device (610), a bus (620), a main memory (630), a read-only memory (640), a mass storage device (650), communication port(s) (660), and a processor (670). A person skilled in the art will appreciate that the computer system (600) may include more than one processor and communication ports. The processor (670) may include various modules associated with embodiments of the present disclosure. The communication port(s) (660) may be any of an RS-232 port for use with a modem-based dialup connection, a 10/100 Ethernet port, a Gigabit or 10 Gigabit port using copper or fibre, a serial port, a parallel port, or other existing or future ports. The communication port(s) (660) may be chosen depending on a network, such a Local Area Network (LAN), Wide Area Network (WAN), or any network to which the computer system (600) connects. The main memory (630) may be random access memory (RAM), or any other dynamic storage device commonly known in the art. The read-only memory (640) may be any static storage device(s) including, but not limited to, a Programmable Read Only Memory (PROM) chips for storing static information e.g., start-up or basic input/output system (BIOS) instructions for the processor (670). The mass storage device (650) may be any current or future mass storage solution, which may be used to store information and/or instructions.

The bus (620) communicatively couples the processor (670) with the other memory, storage, and communication blocks. The bus (620) can be, e.g. a Peripheral Component Interconnect (PCI)/PCI Extended (PCI-X) bus, Small Computer System Interface (SCSI), universal serial bus (USB), or the like, for connecting expansion cards, drives, and other subsystems as well as other buses, such a front side bus (FSB), which connects the processor (670) to the computer system (600).

Optionally, operator and administrative interfaces, e.g. a display, keyboard, and a cursor control device, may also be coupled to the bus (620) to support direct operator interaction with the computer system (600). Other operator and administrative interfaces may be provided through network connections connected through the communication port(s) (660). In no way should the aforementioned exemplary computer system (600) limit the scope of the present disclosure.

While considerable emphasis has been placed herein on the preferred embodiments, it will be appreciated that many embodiments can be made and that many changes can be made in the preferred embodiments without departing from the principles of the disclosure. These and other changes in the preferred embodiments of the disclosure will be apparent to those skilled in the art from the disclosure herein, whereby it is to be distinctly understood that the foregoing descriptive matter to be implemented merely as illustrative of the disclosure and not as limitation.

### ADVANTAGES OF THE PRESENT DISCLOSURE

The present disclosure provides an efficient decoder system.

The present disclosure provides a Field Programmable Gate Array (FPGA) implementation of a polar decoder for physical uplink control channel (PUCCH) format 2 5G new radio (NR) physical layer with reduced resource consumption.

The present disclosure provides reduced resource consumption on a programmable logic (PL) side and reduced usage of look-up tables (LUTs).

The present disclosure provides improved mechanism for generating a reliability sequence in the decoder.

I/we claim:

1. A polar decoder (110), comprising:
a core block (204) comprising a successive cancellation (SC) decoder and a list decoder; and
a cyclic redundancy check (CRC) module (206),
wherein the core block (204) is configured to store one or more pre-calculated reliability sequence for decoding received encoded data bits.

2. The polar decoder (110) as claimed in claim 1, wherein the core block (204) is configured to select the one or more pre-calculated reliability sequence based on an input combination of encoded bits ‘E’ and actual payload bits ‘K’ for the decoding.

3. The polar decoder (110) as claimed in claim 2, wherein the core block (204) is configured to perform sorting on the received encoded bits to decode one or more code words, and wherein the number of steps for sorting to obtain the one or more code words is based on a list size associated with the polar decoder (110).

4. The polar decoder (110) as claimed in claim 2, wherein the core block (204) is configured to provide an output of one or more code words to the CRC module (206) based on the decoding.

5. The polar decoder (110) as claimed in claim 4, wherein the CRC module (206) is configured to determine whether the one or more code words pass or fail a CRC test based on a bit position.

6. The polar decoder (110) as claimed in claim 5, wherein the CRC module (206) is configured to generate an output of the one or more code words based on a CRC pass and a lowest path metric.

7. The polar decoder (110) as claimed in claim 5, wherein the CRC module (206) is configured to output a first code word of the one or more code words based on a CRC fail obtained for all of the one or more code words.

8. A method for decoding in a polar decoder (110), said method comprising:
storing, by a core block (204), one or more pre-calculated reliability sequences;
decoding, by the core block (204), received encoded data bits based on the one or more pre-calculated reliability sequences to output one or more code words to a cyclic redundancy check (CRC) module (206); and
performing, by a cyclic redundancy check (CRC) module (206), a CRC on the one or more code words.

9. The method as claimed in claim 8, comprising selecting, by the core block (204), at least one pre-calculated reliability sequence from the one or more pre-calculated reliability sequences based on an input combination of encoded bits ‘E’ and actual payload bits ‘K’ for the decoding.

10. The method as claimed in claim 8, comprising performing, by the core block (204), sorting on the received encoded bits to decode one or more code words, wherein the number of steps for sorting to obtain the one or more code words is based on a list size associated with the polar decoder (110).

11. The method as claimed in claim 10, comprising determining, by the CRC module (206), whether the one or more code words pass or fail a CRC test based on a bit position.

12. The method as claimed in claim 11, comprising generating, by the CRC module (206), an output of the one or more code words based on a CRC pass and a lowest path metric.

13. The method as claimed in claim 12, comprising generating, by the CRC module (206), an output of a first code word of the one or more code words based on a CRC fail for all the one or more code words.

14. A receiver (108) in a base station (BS), comprising:
a polar decoder, comprising:
a core block (204) comprising a successive cancellation (SCL) decoder and a list decoder; and
a cyclic redundancy check (CRC) module (206),
wherein the core block (204) is configured to store one or more pre-calculated reliability sequence for decoding received encoded data bits.

15. A non-transitory computer readable medium that comprises one or more instructions stored thereupon that when executed by a processor causes the processor to perform operations comprising:
storing one or more pre-calculated reliability sequences;
decoding received encoded data bits based on the one or more pre-calculated reliability sequences to output one or more code words to a cyclic redundancy check (CRC) module (206); and
performing a CRC on the one or more code words.
